(19) United States
(12) Patent Application Publication
(10) Pub. No.: US 2010/0285205 A1
(43) Pub. Date: Nov. 11, 2010

(54) COATING METHOD

(75) Inventors: Pekka Soininen, Helsinki (FI); Sami Sneck, Vantaa (FI)

Correspondence Address: OLIFF & BERRIDGE, PLC, P.O. BOX 320850, ALEXANDRIA, VA, 22320-4850, US

(73) Assignee: BENEQ OY, Vantaa (FI)

(21) Appl. No.: 12/745,330

(22) PCT Filed: Dec. 19, 2008
(86) PCT No.: PCT/FI2008/050769

§ 371 Date: May 28, 2010

(30) Foreign Application Priority Data
Dec. 20, 2007 (FI) 20075944

(51) Int. Cl. C23C 16/52

(52) U.S. Cl. 427/8

(57) ABSTRACT

The invention relates to a process for coating and/or doping a surface of a substrate, an inner surface of a structure or another piece to be processed in a reaction space with the atomic layer deposition method (ALD method). In the process the substrate surface to be processed is subjected alternately to iterated, saturated surface reactions by feeding successive pulses of starting materials into the reaction space. In accordance with the invention, a pulse of starting materials, whose amount is predetermined, is fed into the reaction space; the amount/concentration of the starting materials and/or reaction products thereof is measured in the reaction space during and/or after the pulse or on a continuous basis; the amount of starting materials to be fed into the reaction space in a subsequent cycle is determined on the basis of the measurement results obtained in step b); and a next pulse of starting materials, whose amount corresponds to the measurement results obtained in step c), is fed into the reaction space.

### BACKGROUND OF THE INVENTION

The invention relates to a process in accordance with the preamble of claim 1 for coating a substrate, and in particular to a process for coating and/or doping a substrate surface, an inner surface of a structure or a surface of another piece to be processed in a reaction space with a vapour deposition method, such as atomic layer deposition method (ALD method), in which process the substrate surface to be processed is subjected alternately to repeated, saturated surface reactions of starting materials by feeding successive starting material pulses into a reaction space.

The ALD (Atomic Layer Deposition) method is based on growth controlled by a surface, in which starting materials are introduced onto the surface of the substrate one at a time, at different times and separated from one another. There are also other corresponding methods, such as ALE (Atomic Layer Epitaxy). Conventionally, starting material is applied to the surface of the substrate a sufficient amount such that the available bond positions in the surface will be used. After each starting material pulse the substrate is flushed with inert gas in order that the excess of starting material vapour may be removed to prevent growth in a gas phase. Thus, a chemisorbed monolayer of a reaction product of one starting material will remain on the surface. This layer will react with a next starting material forming a specific, partial monolayer of desired material. After a sufficiently complete reaction an excess of this second starting material vapour is flushed with inert gas, and thus the growth is based on cyclic saturated surface reactions, i.e. the surface controls the growth.

A problem with the above-described conventional way to employ the ALD method is that conventionally starting materials are overdosed in a reaction space, whereby the reaction space must be flushed with inert gas between the feeding of starting materials. Flushing is a slow and expensive operation, which decreases the economic feasibility of ALD technology. In addition, in practice it is almost impossible to implement flushing when inner surfaces of large, confined spaces are to be coated, because large amounts of inert gas are required to implement the flushing and it is difficult to discharge the flushing gas from the space. The amount of flushing gas required increases considerably and the above mentioned disadvantages are further emphasised particularly in cases, where the structures enclosing the volume do not allow utilisation of partial vacuum. It is easy to understand that flushing containers having a size of cubic metres with extremely pure protective gas after every half-cycle producing a layer thickness of less than one Ångstrom consumes enormous amounts, multiples of the container capacity, of such gas. In practice, this alone makes the films extremely expensive. In addition to the large consumption of flushing gas, impurities, such as oxygen, water etc, carried thereby is a further problem. The total amount of these impurities carried by the ample amounts of flushing gases may destroy the whole starting material pulse by oxidizing it in the gas phase already.

### BRIEF DESCRIPTION OF THE INVENTION

The object of the invention is to provide a process by which the above-described problems may be solved. This is achieved by the process in accordance with the preamble of claim 1, which is characterized in that the process comprises the steps of:

a) feeding into a reaction space a pulse of starting material or starting materials;

b) measuring the amount/concentration of the starting materials and/or their reaction products in the reaction space during the pulse or on a continuous basis; and

c) terminating the feeding of the pulse of the starting material or starting materials when the amount/concentration of the starting materials and/or their reaction products reaches a predetermined value.

The preferred embodiments of the invention are disclosed in the dependent claims.

The invention is based on the idea that starting materials are to be dosed into a reaction space in each feed pulse of starting materials substantially an amount required by a substrate surface to be coated such that substantially all starting material fed into the reaction space reacts with the substrate surface, but after the surface reactions there will be substantially no free starting material left in the reaction space. In that case substantially all the starting material fed into the reaction space is consumed for surface reactions of the substrate, and there is sufficiently, however, starting material so that substantially all the substrate surface to be coated participates in the reaction to form a coating layer on the whole surface of the substrate to be coated. To feed an accurate amount of starting materials required into the reaction space is very difficult, and consequently the amount and/or concentration of starting materials fed into the reaction space is measured such that the amount of starting materials to be fed into the reaction space in a subsequent starting material feed pulse may be changed on the basis of the obtained measurement results or the feeding of the starting materials may be disrupted on the basis of the measurement results.

The process and system of the invention have an advantage that flushing is not needed, at least as regards a second flushing, which both speeds up deposition of a coating on a substrate and reduces costs of coating. In addition, the invention enables coating of large pieces that cannot be placed in standard-size ALD reactors. Moreover, it is possible to coat structures that do not tolerate partial vacuum and inner surfaces of large confined spaces.

### DETAILED DESCRIPTION OF THE INVENTION

In the process of the present invention ALD technology or other corresponding technology is utilized in a novel manner such that between the starting material pulses and/or cycles to be fed into a reaction space the reaction space is not flushed with inert flushing gas like in the known art. A starting material cycle refers to two successive feed pulses of starting materials and a flushing therebetween. In accordance with the present invention, starting materials are to be fed into a reaction space in each feed pulse or feed cycle an amount that corresponds substantially to the amount of starting materials needed for surface reactions in the substrate surface to be coated so as to provide one growth layer from the starting materials onto the whole surface to be coated during one pulse/cycle. The process may be employed for eliminating all flushing steps or just one flushing step.

In this application coating refers to providing a growth layer of starting material or starting materials on the substrate surface to be coated and doping the starting material or starting materials in the surface layer or surface structure of the substrate surface to be coated. Correspondingly, in this application a substrate refers to any piece, structure, part thereof to be coated in accordance with the above or the like. In addition, the starting material may comprise one substance or a plurality of substances to be introduced separately into the reaction space or a mixture that contains a plurality of different substances.

In accordance with the present invention, a pulse of starting material or starting materials is first fed into the reaction space. During or after the starting material feed, a gas analyzer is employed to measure the concentration and/or amount of the starting material or starting materials or reaction products obtained from their reactions in the reaction space. The gas analyzer used may be any measuring device or analyzer wherewith gaseous starting materials may be measured. Alternatively, the concentration or amount of the starting materials or reaction products thereof may also be measured on a continuous basis. Gas analyzers suitable for said measurement or analysis include FTIR-analyzers, for instance. In other words, gas analyzers measure how much starting materials or reaction products thereof will be left in the reaction space after the substrate surface has consumed all starting material required for providing one growth layer. In other words, the gas analyzer measures the overdose of the starting materials. Alternatively, if nothing of starting materials or reaction products thereof is left in the reaction space, it may be stated that the substrate surface to be coated has consumed all the starting materials introduced into the reaction space, whereby an accurate amount of starting materials required by the substrate surface to be coated was dosed in the reaction space, or an amount less than required by the surface, i.e. an underdose for providing one growth layer on the whole substrate surface to be coated. Measurement results may also be utilized for detecting when the surface reactions have taken place, upon detecting that the amount/concentration of the starting materials and/or reaction products does no longer change, not at least substantially. This information, in turn, may be utilized for starting a next starting material pulse for interrupting each feeding pulse of the starting materials. In that case the intervals between successive starting material pulses may be minimized and a new pulse may be fed as soon as the previous one is completed.

According to one embodiment of the invention a pulse of starting material or starting materials is fed into a reaction space and the amount/concentration of the starting materials and/or their reaction products is measured in the reaction space during the pulse or on a continuous basis. The feeding of the pulse of the starting material or starting materials is terminated when the amount/concentration of the starting materials and/or their reaction products reaches a predetermined value. The feeding of the starting material or starting materials is terminated when an overdose of starting material or starting materials is detected in the reaction space. The previous steps may be repeated one or more times for feeding a next pulse of starting material or starting materials into the reaction space in order to provide several deposition layers on the substrate.

In an alternative embodiment of the invention a pulse of starting material or starting materials, the amount of which is predetermined, and the amount/concentration of the starting materials and/or their reaction products in the reaction space is measured during the pulse and/or after the pulse or on a continuous basis. The amount of starting material or starting materials to be fed into the reaction space in the next pulse is determined on the basis of the measurement results or the amount of the starting material or starting materials fed during the previous pulse. Furthermore, on the basis of these measurement results it is deduced, according to what is set forth above, whether an overdose or an underdose of starting materials was fed into the reaction space. On the basis of these deductions, there will be determined the amount of starting materials to be introduced into the reaction space in a subsequent feed pulse of the starting materials. On the basis of the determination and the measurement results the amount of starting materials to be fed into the reaction space in the subsequent starting material feed pulse is either reduced or increased in relation to the amount of starting materials fed into the reaction space in the previous feed pulse. In other words, if the measurement results indicate an overdose of starting materials the amount of the starting materials to be fed in the next feed pulse into the reaction space is reduced in relation to the amount of the starting materials fed into the reaction space in the previous pulse. Correspondingly, if the measurement results indicate an underdose of starting materials, or an accurate dose, if any, which is impossible to distinguish from underdose on the basis of the measurement results, the amount of starting materials to be fed into the reaction space in the next feed pulse is increased in relation to the amount of starting materials fed into the reaction space in the previous pulse. On the basis of the measurement results it is possible to change the amount of starting materials to be fed in the next pulse for a predetermined amount or in relation to the magnitude of underdose or overdose. Thereafter this changed amount, determined on the basis of the measurement results, is fed into the reaction space for providing one growth layer on the surface of the substrate to be coated.

When it is desired to grow a plurality of growth layers on the substrate, the above-described process is repeated several times such that the values measured during every preceding starting material feed cycle and the amount of starting materials fed in the preceding pulse are used for adjusting the amount of starting materials to be fed in a subsequent pulse. Thus, the amount of starting materials to be fed into the reaction space in successive feed pulses will be made to correspond, on average, substantially to the amount of starting materials required and/or received by the substrate surface to be coated. In that case, on average substantially all the starting material fed into the reaction space reacts and binds to the surface of the substrate to be coated, whereby after the surface reactions there will be substantially no starting materials and/or reaction products left in the reaction space, which have not participated in the surface reactions. This kind of iterating starting material feed does not necessitate flushing, because no large overdoses will be fed into the reaction space. In accordance with the process of the invention, in successive starting material feed pulses there is fed starting material in an amount that is determined on the basis of the amount of the starting materials fed in the preceding starting material pulse and the amount of starting materials or reaction products found in the reaction space during and/or after the feed pulse. Thus, during the successive feed pulses the amount of starting materials to be fed approaches the correct amount necessary for the substrate surface reactions at least up to a predetermined accuracy. It is possible to continue carrying out the process until a predetermined number of starting material feed pulses and/or a predetermined thickness of coating have been reached.

In accordance with what is stated above, in the present invention, the ALD method for coating and/or doping a surface of a substrate utilizing a predetermined starting material pulse comprises steps of 1) feeding into a reaction space a pulse of starting material or starting materials, the amount of which is predetermined;

2) measuring the amount/concentration of the starting materials and/or the reaction products thereof in the reaction space during and/or after the pulse or on a continuous basis;

3) determining the amount of starting material or starting materials to be fed into the reaction space in the next pulse on the basis of the measurement results obtained in step 2) and on the basis of the amount of starting materials fed in step a); and

4) feeding into the reaction space a subsequent cycle of starting material or starting materials, the amount of which corresponds to that determined in step c).

As the process is repeated several times successively, step d) always constitutes step 1) of the subsequent round in iteration. In this manner the adjustment of the ALD method may be implemented as a continuous process, which is to optimize the feeding of starting materials into the reaction space.

In accordance with the process of the present invention, it is possible to feed into the reaction space two or more starting materials successively or simultaneously during steps 1) and/or 4) or during one feed pulse. In other words, in step 1), for instance, there is fed into the reaction space both starting material A and starting material B simultaneously, and they both participate in surface reactions of the substrate or the reaction product produced thereby participates in surface reactions of the substrate so as to provide one growth layer on the substrate surface to be grown. In that case, a gas analyzer measures the amount or concentration of the starting materials A and/or B or the reaction product A+B thereof in the reaction space, and on the basis of this measurement the amount of the starting materials, e.g. A and B, to be fed into the reaction space in a subsequent feed pulse will be adjusted. Alternatively, the starting materials may be fed into the reaction space during steps 1) and/or 2) or during one feed pulse successively such that starting material A is first fed into the reaction space and thereafter starting material B, whereby the amount or concentration of the starting materials A and B or the reaction products thereof may be measured during and/or after feeding the starting material A and during and/or after feeding the starting material B. On the basis of this measurement it is possible to determine again the amount of starting materials, e.g. A and B, to be fed in a subsequent feed pulse, or alternatively, in a subsequent feed cycle. This means that in successive feed cycles, e.g. 1) and 2), of the starting materials it is possible to feed always the same starting materials into the reaction space. In addition, the amount of starting materials to be fed in each feed cycle may be adjusted on the basis of the measurement results uniformly such that the amount of all starting materials will be altered in the same manner, or alternatively, the amount of each starting material may be adjusted separately on the basis of the obtained measurement results. Further, it is possible to feed the starting materials into the reaction space as a ready-made mixture of two or more starting materials. Thus, the measurement of the starting materials or the reaction products thereof in the reaction space and/or determination of the amount of a starting material to be fed next may be carried out after feeding all the starting materials fed in one feed cycle or separately after feeding each successive feed pulse. It is also possible to feed a standard dose of a second starting material and the amount of the second starting material is adjusted in the above-described manner. It should be noted that certain moieties of A and B bind to the substrate surface and it is possible to measure unbound reaction product(s).

In the process of the invention it is possible to feed different starting materials into the reaction space in successive starting material feed pulses. In other words, in step 1), for instance, starting material A is fed into the reaction space, and in step 2) starting material B. In that case, the measurement results obtained may be utilized such that when a feed pulse of first starting material A is fed into the reaction space in step 1) and its measurement is carried out according to step 2), this measurement result is used in step 4) together with the amount of fed starting material A to determine the amount to be fed of a second starting material B. And again, measurements are performed on starting material B, and the measurement results are used again for determining the amount of a starting material, e.g. A and some other starting material, to be fed in a subsequent pulse.

A further way to utilize the process of the present invention is to perform it separately on each starting material to be fed into the reaction space, whereby the amount of each starting material may be adjusted separately. This means that determination of the amount of each starting material to be fed into the reaction space employs only the measurement results of the preceding feed pulse of the same starting material and the amount of the starting material fed during the preceding feed pulse thereof. In other words, the amount/concentration of the starting material A fed into the reaction space in the feed pulse is measured, and in accordance with these measurement results and the amount of the fed starting material A there is determined the amount of the starting material A to be fed in the subsequent feed pulse, or in the subsequent feed cycle, in which starting material A is fed, the amount of the starting material A to be fed. The same procedure may be performed separately on starting material B. Alternatively, for determining the amount of a specific starting material it is possible to use the measurement results of another starting material or other starting materials.

The above-described measurement of starting materials/reaction products and the adjustment of the amount of starting materials to be fed on the basis of the measurements may be continued on achieving a balance with a predetermined accuracy, where the amount of fed starting materials and/or reaction products thereof corresponds substantially to the amount of starting materials and/or reaction products necessary for surface reactions of the substrate surface to be coated so as to provide one growth layer from the starting materials onto the whole substrate surface to be coated during one cycle. This means that upon finding a balance with a predetermined accuracy for the amount of starting materials to be fed, feeding of starting materials is continued in successive cycles by using said balanced amount. The balanced amount may be a minor overdose or underdose of the starting materials.

When a first feed pulse of starting material or starting materials is fed into the reaction space in the process of the invention in order to provide a first growth layer on the substrate, i.e. as substrate coating is initiated, in the first feed pulse an overdose of starting materials is fed into the reaction space in accordance with the above-described step 1) such that the amount of the fed starting materials or reaction products thereof exceeds the amount necessary for the surface reactions of the surface to be coated. In that case, on the basis of the measurements it is possible to determine immediately the excess of the starting materials or reaction products thereof, and consequently it is possible to further adjust the amount of starting materials to be fed in a subsequent feed pulse. Alternatively, the coating of the a substrate may be initiated by feeding an underdose of starting materials into the reaction space in the first pulse in accordance with the above-described step 1) such that the amount of fed starting materials and/or reaction products thereof is less than the amount necessary for the surface reactions of the substrate surface to be coated. Thereafter, in a next feed pulse it is possible to increase the amount of starting materials to be fed. Underdosing leaves it unclear, however, how large underdosing is concerned, i.e. the actual need for starting materials is not known, unlike in overdosing situations. On the other hand, as a result of overdosing there will be left in the reaction space reaction products or starting materials that do not bind, but they may remain in the reaction space as dust or other impurities. In the first feed pulse the amount of starting materials to be fed into the reaction space may be estimated or predetermined, for instance on the basis of previous measurement data.

After each fed starting material feed pulse and the relating measurement stage it is determined whether the fed feed pulse was an overdose or an underdose. In an overdose case the amount of starting materials to be fed into the reaction space in a subsequent feed pulse will be reduced as compared with the amount of starting materials fed in the previous cycle. In an underdose case, in turn, the amount of starting materials to be fed into the reaction space in a subsequent pulse will be increased as compared with the amount of starting materials fed in the previous pulse. The amount of starting materials may be changed in relation to the magnitude of overdose or underdose obtained in the measurement or the change may be made stepwise, whereby the amount of starting materials to be fed will be changed for a predetermined amount. In addition to successive feed pulses, the above principle may also be used for implementing successive feed cycles consisting of two successive feed pulses. In that case, the measurements of the starting materials and/or reaction products thereof are carried out during the cycle and the amount of starting materials is not adjusted on the bases of the measurement results until for the next cycle.

Yet according to one embodiment of the invention pulses of a starting material or starting materials are fed sequentially into reaction space, the pulses being of predetermined amount, i.e. a predetermined amount of starting material or starting materials is fed into the reaction space in one pulse. Preferably these pulses are short. At the same time the amount/concentration of the stating materials and/or their reaction products in the reaction space are measured during the pulse and/or after the pulse or on a continuous basis. Therefore it may be defined by measuring when an overdose of a starting material or starting materials is fed into the reaction space. For example, when a predetermined amount/concentration of staring materials or their reaction products in the reaction space is achieved, the feeding of the pulses of a starting material or starting materials into the reaction space is terminated. In other words according to this embodiment the feeding of the starting materials may be disrupted between the feeding pulses, whereby a feeding pulse need not be terminated. Additionally, according to this embodiment the first pulse need not be fed by estimation, whereby a large overdose is not needed. In other words in this embodiment short feed pulses are fed until a predetermined amount or concentration of starting materials or their reaction products is reached in the reaction space, after which the feeding of the feed pulses is terminated and the method may be continued in a corresponding way with next starting material or starting materials.

The process of the present invention may be implemented using a conventional reaction chamber of an ALD reactor and/or a low-pressure chamber as the reaction space. Because the process of the invention eliminates the need for flushing of the reaction space, in principle, it is possible to use as the reaction space any space in which the starting material may be introduced. The reaction space may be provided such that the substrate to be coated may be placed inside the reaction space. Further, the reaction space may or may not comprise partial vacuum.

The process of the invention is particularly suitable for coating inner surfaces of large, confined spaces. In that case, the confined space serves as the reaction space and its inner surface serves as the substrate to be coated. A confined space is very difficult and slow to flush using prior art technology, so the present invention solves the problem associated therewith enabling inner surfaces of various tanks, chambers, tubes, pipework and the like closed or closable spaces to be coated with ALD technology. In that case, the starting materials are introduced into the confined space and they are allowed to react to form a growth layer on the inner surface of the confined space.

It should be noted that all the above defined features may be used in an embodiment, in which the starting material pulse is terminated on the basis of the obtained measurement result, or in an embodiment, in which feeding pulse of a predetermined size, is always fed into the reaction space.

The reaction space may be further provided with a fan, a blade mixer or a like mixing device for mixing and/or circulating the starting materials introduced in the reaction space. By mixing and circulating the starting materials inside the reaction space it is made sure that the starting materials react as completely as possible and find their way to the surface to be coated.

The method according to the present invention may be used for passivating a surface, providing a diffusion layer, corrosion protection and providing an antireflection (AR) and reflection (HR) or other optical coatings. Furthermore, the method allows the surface properties of a substrate y be altered, such as biocompatibility, hydrophilicity, hydrophobicity, oleophilicity, oleophobicity and catalycity. Further, by the method surfaces may be smoothened, conductive coatings, transparent conductive coatings and electrically resistive coatings may be provided. In the present invention glass, plastic, ceramic material, metal or any other suitable material may be used as a substrate.

It is obvious to a person skilled in the art that as technology progresses, the basic idea of the invention may be implemented in a variety of ways. Thus, the invention and the embodiments thereof are not restricted to the above-described examples, but they may vary within the scope of the claims.

1.-26. (canceled)

27. A process for coating and/or doping a substrate, an inner surface of a structure or a surface of another piece to be processed in a reaction space with a vapour deposition method, such as atomic layer deposition method (ALD method), in which process the substrate surface to be processed is subjected alternately to repeated saturated surface reactions of starting materials by feeding successive starting material pulses into a reaction space, wherein the process comprises the steps of:
a) feeding into the reaction space a pulse of starting material or starting materials;
b) measuring the amount/concentration of the starting materials and/or their reaction products in the reaction space during the pulse or on a continuous basis; and
c) terminating the feeding of the pulse of the starting material or starting materials when the amount/concentration of the starting materials and/or their reaction products reaches a predetermined value.

28. The process of claim 27, wherein the process comprises repeating the steps a), b) and c) one or more times for feeding a next pulse of starting material or starting materials into the reaction space for providing one or more deposition layers on the substrate.

29. The process of claim 27, wherein the process comprises feeding in step a) starting material or starting materials into the reaction space and terminating the feeding of the pulse according to step c) when an overdose of starting material or starting materials is detected by the measurement of step b).

30. The process of claim 27, wherein the process comprises feeding in step a) into the reaction space a pulse of starting material or starting materials the amount of which is predetermined, and measuring in step b) the amount/concentration of the starting materials or their reaction products in the reaction space during the pulse and/or after the pulse or on a continuous basis and terminating in step c) the feeding of the feed pulse of the starting material into the reaction space when the predetermined amount of starting material or starting materials according to step a) is reached.

31. The process of claim 30, wherein the process comprises determining before feeding next starting material or starting materials and before repeating steps a), b) and c), the amount of starting material or starting materials fed into the reaction space in the next pulse on the basis of the measurement results obtained in step b) and the amount of starting materials fed in step a).

32. The process of claim 31, wherein determination of the amount of starting material or starting materials to be fed into the reaction space in a subsequent pulse is performed after feeding all the starting materials fed in step a) or separately after feeding each successive starting material.

33. The process of claim 30, wherein the process comprises repeating steps a), b) and c) until achieving a balance with a predetermined accuracy, in which the amount of the fed starting materials and/or reaction products thereof substantially corresponds to the amount of the starting materials and/or reaction products needed for surface reactions of the substrate surface to be coated so as to provide one growth layer from the starting materials onto the whole surface of the substrate to be coated during one pulse.

34. The process of claim 30, wherein the process comprises initiating the coating of the substrate by feeding in the first pulse an overdose of materials into the reaction space in accordance with step a) such that the amount of the fed starting materials and/or reaction products thereof exceeds the amount needed for surface reactions of the substrate surface to be coated.

35. The process of claim 30, wherein the process comprises initiating the coating of the substrate by feeding in the first pulse an underdose of starting materials into the reaction space in accordance with step a) such that the amount of the fed starting materials and/or reaction products thereof is less than the amount needed for surface reactions of the substrate surface to be coated.

36. The process of claim 30, wherein the process comprises reducing the amount of the starting materials to be fed into the reaction space in a subsequent pulse as compared with the amount of starting materials fed in the previous pulse, when the measurement results in step b) indicate an overdose of starting materials.

37. The process of claim 30, wherein the process comprises increasing in step c) the amount of starting materials to be fed into the reaction space in a subsequent pulse in step d) as compared with the amount of starting materials fed in the previous cycle, when the measurement results in step b) indicate an underdose of starting materials.

38. The process of claim 36, wherein the amount of starting materials to be fed into the reaction space in a subsequent pulse is reduced or increased in relation to the measurement result obtained in step b).

39. The process of claim 27, wherein a reaction chamber and/or a partial vacuum chamber of an ALD apparatus is used as the reaction space.

40. The process of claim 27, wherein that any confined space, into which the starting materials may be introduced, is used as the reaction space.

41. The process of claim 27, wherein a closed tank, chamber, tube, pipework or the like space, whose inner surfaces form a substrate to be coated and/or doped, is used as the reaction space.

42. The process of claim 37, wherein the amount of starting materials to be fed into the reaction space in a subsequent pulse is reduced or increased in relation to the measurement result obtained in step b).
